(19) United States
(12) Patent Application Publication
(10) Pub. No.: US 2017/0188482 A1
(43) Pub. Date: Jun. 29, 2017

(54) COMPARTMENTALIZED HEAT EXCHANGER IN INDUSTRIAL COMPONENT SYSTEM

(71) Applicant: John Stockdale, Regina (CA)

(72) Inventor: John Stockdale, Regina (CA)

(21) Appl. No.: 15/389,683

(22) Filed: Dec. 23, 2016

(30) Foreign Application Priority Data
Dec. 29, 2015 (CA) 2914383

(51) Int. Cl. H05K 7/20; F28F 19/04; F28F 27/00; F28F 9/00

(52) U.S. Cl. CPC H05K 7/2039; F28F 9/001; F28F 19/04; F28F 27/00; H05K 7/20136; F28F 2009/004

(57) ABSTRACT

In a cooled component system, a heat exchanger mounted on a surface of the industrial component is housed in an isolated access compartment adjacent to but separated from the primary compartment containing the industrial component. Housing the heat exchanger in a separately accessible compartment permits access to the heat exchanger for cleaning or other purposes without having to shut down the industrial component being cooled. A means for moving a cooling media over the surface a the heat exchanger might also be included to maximize heat exchange.

### FIELD OF THE INVENTION

This invention is in the field of industrial equipment which produces heat in operation requiring heat evacuation or exchange, and more specifically relates to heat exchangers or “heat sinks” configured to manage heat produced from such a source.

### BACKGROUND

Electrical components such as microprocessors, motor drives and voltage regulators produce heat as part of their normal operation. One of the types of components which are in this category are variable frequency drives (also known in industry as VFDs). As these electronic assemblies have become more complex, with higher processor speeds, higher operating frequencies, smaller size, and complex power management arrangements, significant amounts of heat can be generated. This heat presents a problem as undissipated it leads to increased temperature in the assembly. Excessive heat can degrade the performance of electrical components, decrease reliability and potentially lead to component failure. As a result, it has been realized for some time that methods and apparatus are required as part of electrical and electronic assemblies in order to dissipate excess heat and maintain optimal operating temperatures for these components.

One approach to solving the problem of heat dissipation in electronic devices, including VFDs or the like, has been to include a heat exchanger component typically referred to as a heat sink. Heat sinks are generally designed to be in direct contact with components that generate heat, and to draw heat away from a component by simple heat transfer. Heat is then transferred in turn to an external cooling medium, typically air. In general, the heat sink will be fashioned to provide increased surface area on the portion in contact with the cooling medium. A series of vanes is a common design for heat sinks. See for example U.S. Pat. No. 6,503,626—GRAPHITE BASED HEAT SINK (Norley et al.).

In some cases, the cooling medium can be moved in order to increase the rate at which heat can be dissipated via the heat sink and maintain clear flow paths for same. For example, it is common to use a blower in order to move air across an air heat sink. See for example U.S. Pat. No. 4,884,631 (Rippel)—FORCED AIR HEAT SINK APPARATUS.

An inherent limitation of heat sink arrangements is that over time the efficiency of the heat sink can degrade as a result of accumulation of dust, dirt and other contaminants. These contaminants create a barrier between the heat sink material and the cooling medium, thereby reducing the efficiency of heat transfer away from the component being cooled to the cooling medium. This is a particularly serious problem when components are being operated in challenging environments that have significant contamination with airborne particles, such as occurs in mining operations and the like.

Electrical components such as variable frequency drives and the like are often used in industrial applications where they are containerized so that they are portable and can be moved between work sites. For example, the mounting of one or more variable frequency drive units in a movable container is often also interchangeably referred to as a power sled, or other abbreviations or nicknames can also be used. The use of these power sleds is often in very challenging work environments, maximizing the number of occurrences for necessary cleaning of a heat exchanger on the VFD in question. These are typically also very high voltage work applications where safety being paramount, it is simply not possible to operate the VFD when there is any human access to the components thereof, which would be required when cleaning was undertaken.

From time to time it becomes necessary to clean the heat sink in order to restore cooling efficiency. Prior art heat sink arrangements suffer from a problem in that the components being cooled are in the same physical compartment as the heat sink; and so in order to clean the heat sink, it is prudent if not essential to turn off the electronic components in order to avoid inadvertent damage during the cleaning process, especially when it is necessary to use cleaning agents that are electrical conductors.

A heatsink arrangement that is capable of safe access during operation of the related component is, it is believed, widely palatable in industry.

### SUMMARY OF THE INVENTION

The present invention relates to a novel heat sink arrangement on an industrial component such as a variable frequency drive or the like which is containerized for use in industrial environments. The containerized system including at least one industrial component in question may be portable or may be permanently installed. At least one variable frequency drive or other industrial component is mounted in at least one corresponding primary container compartment, along with other related equipment. Incoming power supply and outgoing power drive generated by electrical components in industrial drive applications is one particular application in which the present invention would be particularly applicable.

The invention comprises a containerized industrial component system, containing at least one heat generating industrial component located within a primary compartment thereof. Each of the at least one heat generating industrial components which is the subject of cooling, within the scope of the present invention, has at least one heat exchanger or heat sink attached to a surface thereof, which protrudes through a wall of the related primary compartment to an isolated access compartment related to that particular heat sink. The isolated access compartment has the necessary ventilation thereon—such as openings, grills or the like, through which air can be circulated to cool the heat exchanger.

Certain embodiments of the overall system of the present invention might include more than one heat generating industrial component, which might be mounted in one or more primary compartments. The heat exchanger related to each heat generating industrial component could be located within its own freestanding isolated access compartment, or more than one heat exchanger in embodiments containing more than one heat generating industrial component could be located within the same isolated access compartment. Both such approaches will be understood to those skilled in the art and are understood to be within the scope of the present invention.

The containerized heat generating industrial component system of the present invention comprises at least one heat generating industrial component mounted within a primary compartment. The primary compartment shares a wall with an isolated access compartment. The at least one heat generating industrial component includes a heat exchanger or heat sink mounted on one surface thereof, and is mounted in such a way that the heat exchanger or heatsink is mounted through the wall which is shared between the primary compartment and the isolated access compartment, so that the at least one heat generating industrial component is located within the primary compartment, and the related heat exchanger is located within the corresponding isolated access compartment. Heat can then be drawn off of the heat generating industrial component, such as the VFD or the like, via the isolated access compartment. Heat within the primary compartment is minimized, and operation of the heat generating industrial component can continue if there is ever any reason to clean or access the heat exchanger via the isolated access compartment.

The present application discloses a novel heat sink arrangement where the heat sink is located in a compartment separate from and adjacent to the component that it cools, and yet maintains sufficient thermal contact with the component to be able to effectively maintain the component within a desired temperature range during operation. This novel arrangement allows for cleaning of the heat sink without having to shut down or otherwise take offline the component that the heat sink serves. Operating heat within the primary compartment is also minimized by the protrusion of the heat exchanger into a separate operating area outside of the primary compartment.

Various types of ventilation can be placed within the isolated access compartment—vents, grills or the like allowing for the passage of air in either a passive or forced fashion there across. It is specifically contemplated that powered blowers could be used to blow a maximum volume of air through the isolated access compartment and maximize the cooling ability of the heat exchanger.

### BRIEF DESCRIPTION OF THE DRAWINGS

While the invention is claimed in the concluding portions hereof, preferred embodiments are provided in the accompanying detailed description which may be best understood in conjunction with the accompanying diagrams where like parts in each of the several diagrams are labeled with like numerals, and where:

FIG. 1 is a perspective view of an embodiment of containerized heat generating industrial component system in accordance with the present invention, showing the door on the isolated access compartment for the heat exchanger closed;

FIG. 3 is a side view of the embodiment of FIG. 1;

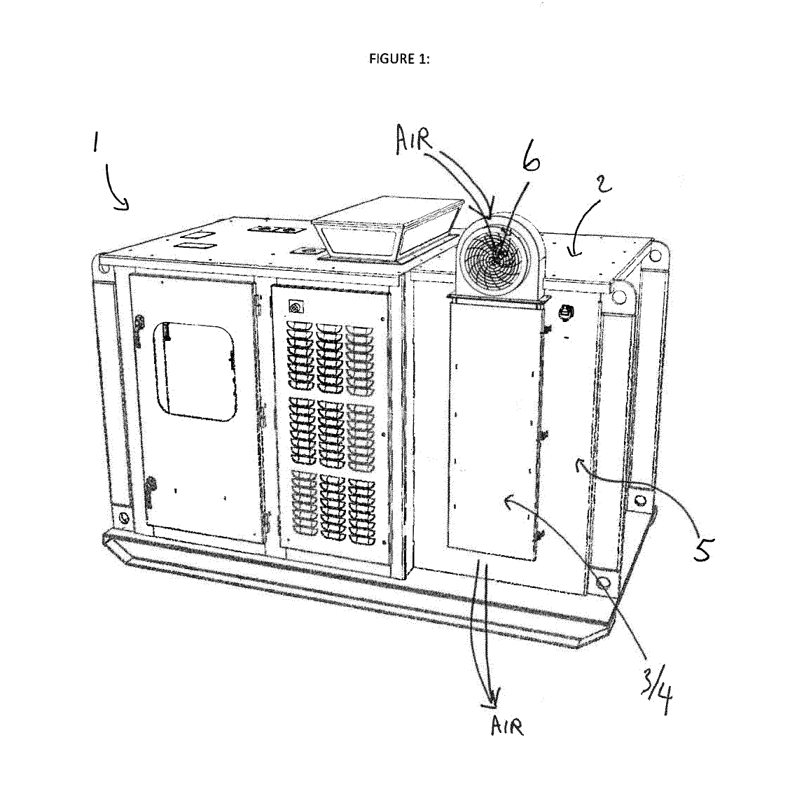

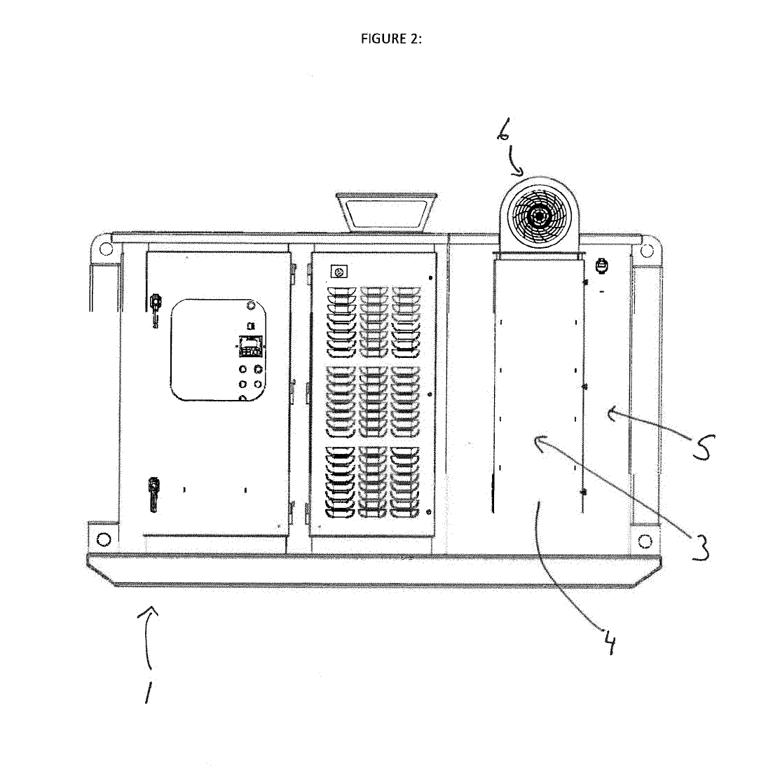

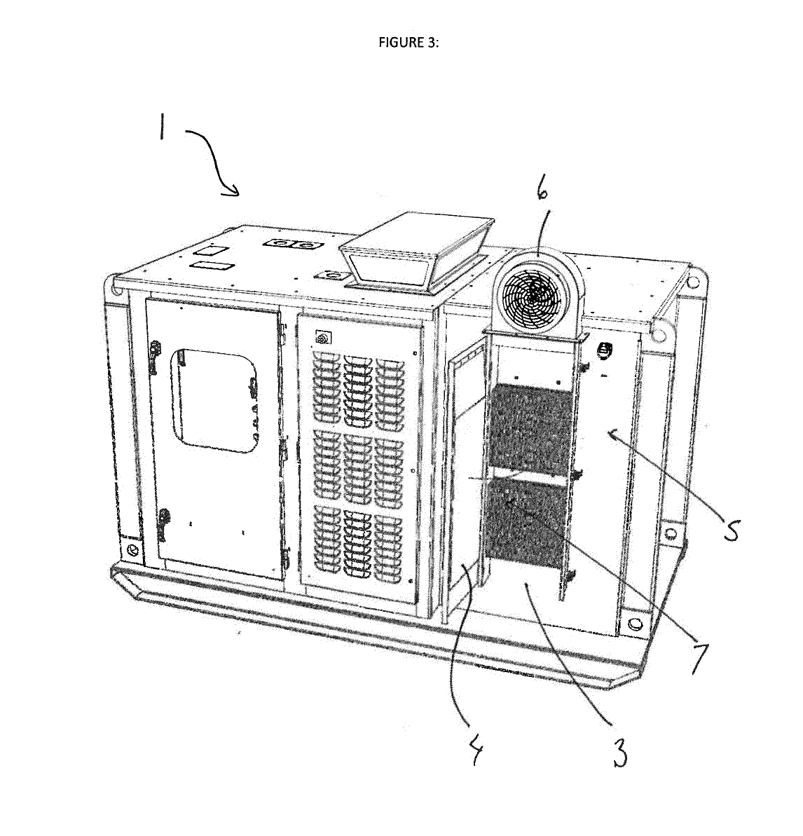

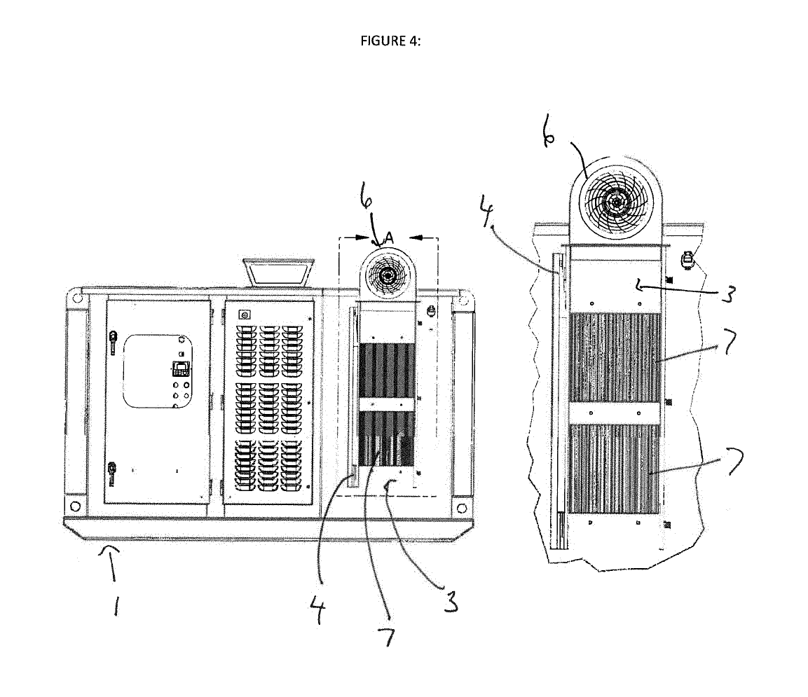

FIG. 2 shows the embodiment of FIG. 1 with the door on the isolated access compartment open;

FIG. 4 is a side view of the embodiment of FIG. 2 also showing an expanded view of an exemplary heat sink;

FIG. 5 is a top view of the embodiment of FIG. 1;

FIG. 6 is a top view of the embodiment of FIG. 2, with the door of the isolated access compartment open;

FIG. 7 is a back view of the embodiment of FIG. 2; and

FIG. 8 is a top view of an embodiment of the invention with a plurality of isolated access compartments.

### DETAILED DESCRIPTION OF THE INVENTION

As outlined above, the present invention relates to a novel compartmentalized heat exchanger in a heat producing industrial component system. Various types of industrial component systems would include heat producing industrial components, such as an electric drive, variable frequency drive or VFD, or any other type of a mechanical or electrical component which generates heat in operation. Some heat producing industrial components might be cooled by providing a flow of a cooling media that contacts the surface of the heat exchanger. The cooling media may be fluid, where others, which are the focus of the present invention, where one or more vane heat exchangers or heat sinks attached to the surface thereof are cooled by a flow of air as the cooling medium. A plurality of vanes on the heat exchanger allows for increased efficiency in the dissipation of heat from the operation of the component into the surrounding environment.

The at least one heat producing industrial component is contained within a primary compartment. A heat exchanger mounted on one surface of each heat producing industrial component is mounted extending through a shared wall between the associated primary compartment and an isolated access compartment, whereby the heat exchanger surface within the isolated access compartment allows heat to be drawn away from the primary compartment and the heat exchanger can be accessed during operation of the equipment inside of the primary compartment safely and without the need to decommission the equipment, or otherwise stop the operation of the equipment while cleaning and/or maintenance of the heat exchanger was being performed. While being separately located for safe access during operations, the heat exchanger maintains sufficient thermal contact with the heat producing industrial component to which it corresponds to be able to effectively maintain the heat producing industrial component within a desired temperature range during operation.

In some instances, the desired temperature range may be from about −55° C. to about 125° C., or from about −40° C. to about 85° C., or from about 0° C. to 70° C. Those of skill in the art will select a temperature that is compatible with the optimal operation of the components present in the system.

The at least one heat producing component is containerized in either a stationary or movable enclosure. In the case of a movable enclosure, these are oftentimes referred to as equipment sleds or containers. FIG. 1 shows one perspective view of an equipment sled 1 in accordance with the remainder of the present invention.

The equipment sled 1 comprises a mobile container within which one or more heat producing industrial components and other components can be assembled for use in various industrial applications, such as power supply or the like. Any type of portable or permanently mounted heat producing industrial components which are typically containerized in either a portable or permanent enclosure could be encompassed within the scope of the present invention.

The equipment sled 1 comprises, with specific reference to the present invention, a primary compartment 2 as well as an isolated access compartment 3. The primary compartment 2, which cannot be seen directly in this Figure but is shown by a dotted line arrow, would contain at least one heat producing industrial component therein. The heat producing industrial component would include a heat exchanger or heat sink on one surface thereof, by which heat can be exchanged to the surrounding environment. The primary compartment 2 would include a wall 5 which was shared with the isolated access compartment 3. The isolated access compartment 3, which is also shown with a door 4, is the compartment into which, by virtue of the mounting of the heat exchanger in an aperture through the wall 5, air could be moved for the sake of heat exchange. By opening the door 4, the heat exchanger could be accessed during operation of the sled 1, without the need to open any access doors or panels to the primary compartment 2.

Also shown is a blower 6 mounted on the top of the isolated access compartment 3. The isolated access compartment 3 could include one or more air egress areas, being vents, grills or the like, through which air could enter and exit the isolated access compartment 3 and access the heat exchanger located therein. By the mounting of a blower 6 on the isolated access compartment 3, maximum airflow through the isolated access compartment 3 during operation of the sled 1 can be achieved. The airflow in a top-mounted blower scenario such as is shown in this Figure, is shown by two airflow arrows on the drawing.

In some cases, it may be desirable to provide a fluid as the cooling media, rather than air, as the heat transfer capacity of a fluid is significantly greater. In this case, it will be recognized that a fluid cooling media can be provided in either an open or closed loop type of system. Such system might also take advantage of various conduits and pumps in order to supply the cooling media and move it through the isolated access compartment, thereby drawing heat from the exchanger into the cooling medium.

The isolated access compartment 3 is not shown in full detail in this Figure, but the overall concept of the present invention can be appreciated—the presence of the primary compartment 2 sharing a wall 5 with the isolated access compartment 3, through which a passive air heat exchanger could be mounted, and by virtue of which the heat exchanger could be accessed during operation of the sled 1 will be understood.

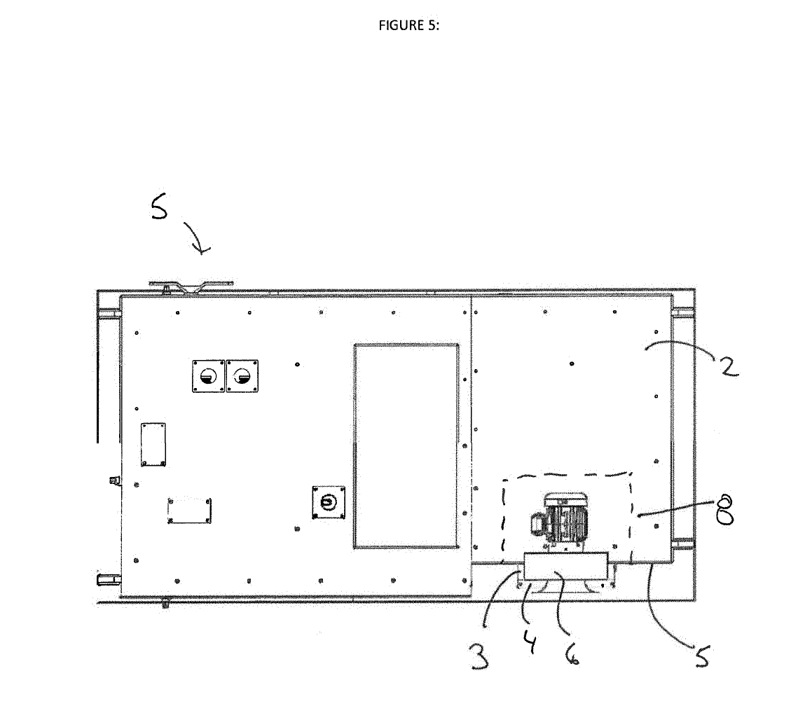

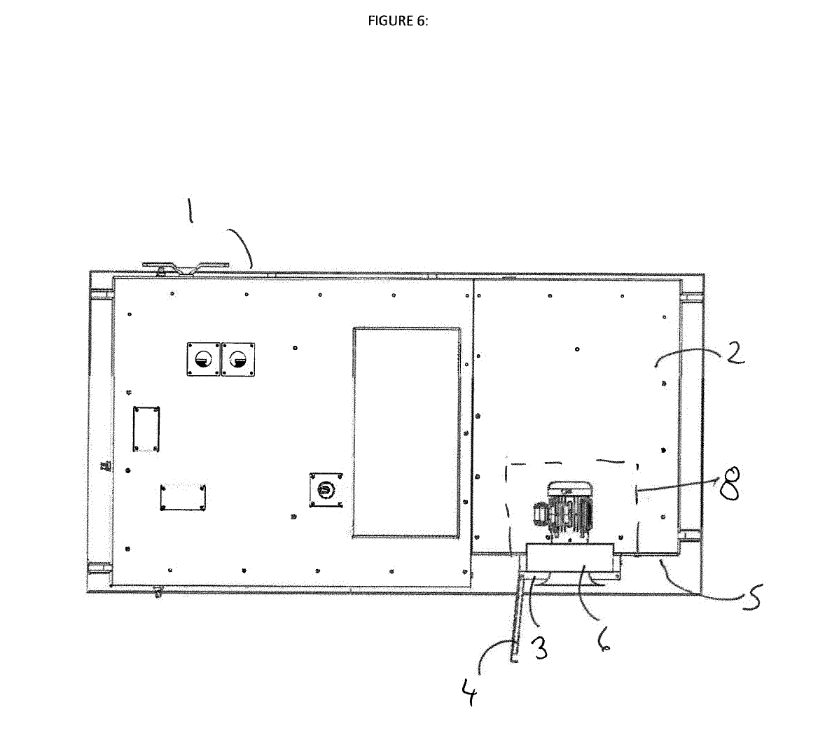

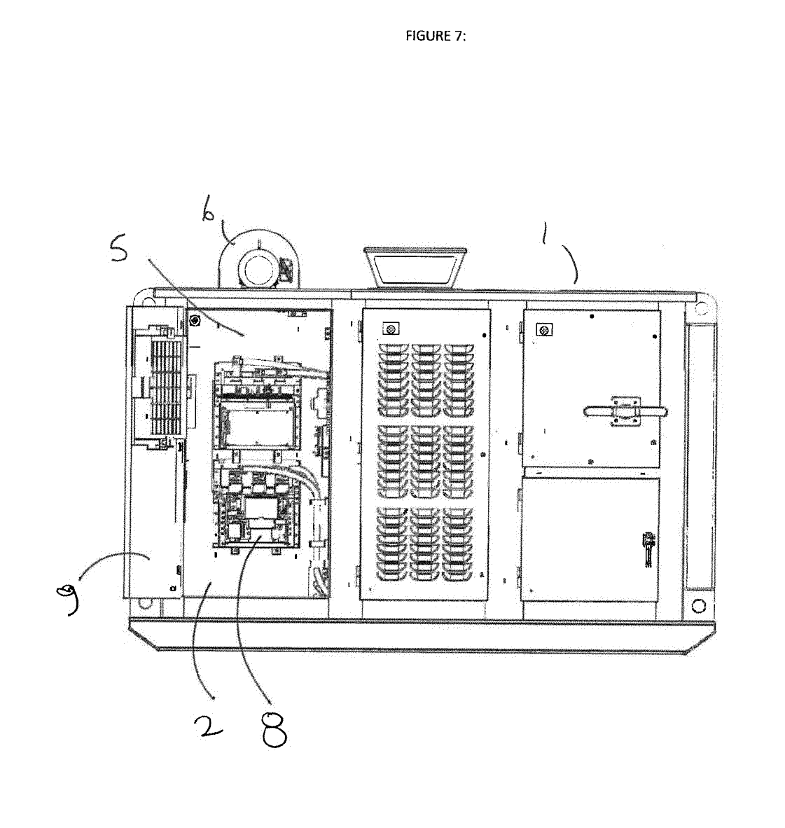

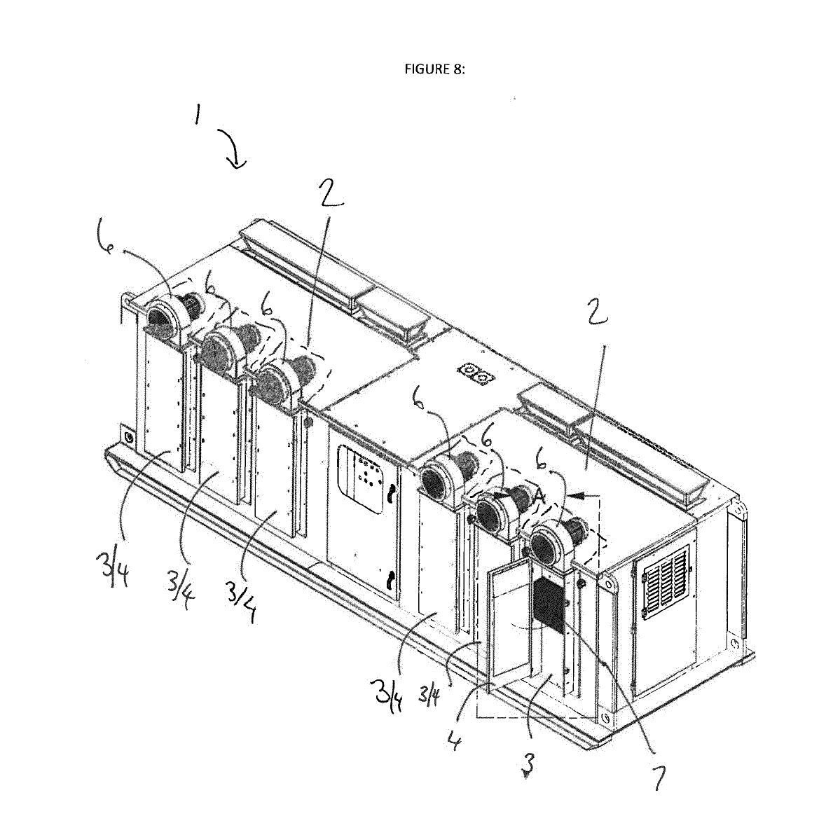

FIG. 3 is a side view of the embodiment of the system 1 of FIG. 1, showing the access door 4 to the isolated access compartment 3 in a closed position. Referring next to FIG. 3, the heatsink or heat exchangers 7 are shown. In this particular case, two heat exchangers 7 are shown, which would be mounted to one surface of at least one heat producing industrial component within the primary compartment 2, and which extend through the wall 5 into the isolated access compartment 3. As can be seen in this particular Figure where the door 4 is opened, air flow from the blower 6 would come through the isolated access compartment 3 to exhaust at the bottom thereof and would blow over the vanes of the heat exchangers 7 in doing so.

FIG. 4 is a side view of the embodiment of FIG. 3, showing the door 4 of the isolated access compartment 3 in an open position. The two heat sinks 7 are shown, as is the blower 6 mounted at the top of the isolated access compartment 3. FIG. 4 also includes a detailed view of the two heat exchangers 7 mounted within the isolated access compartment 3.

The system 1 which is shown in these Figures is shown as a portable equipment sled. It will, however, be understood that the system 1 could also, rather than being manufactured and deployed in a portable equipment sled or container, also be designed for use in conjunction as a permanent installation with one or more heat producing industrial components in a permanent location or permanent primary compartment. Both such approaches are contemplated within the scope of the present invention, and it is contemplated that the system and method of the present invention for compartmentalizing the heat exchanger from at least one heat producing industrial component would be particularly useful in portable containerized industrial assemblies for use in demanding work environments, such as underground mining or other similar industrial applications.

There would be at least one isolated access compartment corresponding to each primary compartment containing industrial components requiring cooling. Each isolated access compartment 3 shares a wall 5 with its corresponding primary compartment 2 as shown in FIG. 1 and capture 3, whereby the heat producing industrial component or components therein which require cooling within the primary compartment are mounted with their heat exchangers extending through that shared wall 5, such that the heat exchanger 7 for each industrial component is present within the isolated access compartment 3 corresponding to the primary compartment 2 in question. The primary compartment 2 as well as the isolated access compartment or compartments 3 corresponding thereto will each include doors or the like 4 for the isolation or protection of equipment contained therein, during operation or movement of the system 1.

As outlined, the system 1 of the present invention might comprise more than one primary compartment, but in any event at least one primary compartment would be in the system 1. Each primary compartment 2 contains at least one heat generating industrial component requiring heat exchanger cooling. At least one isolated access compartment 3 corresponds to each primary compartment 2, and each isolated access compartment 3 has at least one heat exchanger 7 for a related heat producing industrial component facing therein. In an embodiment where a single primary compartment 2 contains more than one industrial component with the heatsink attached thereto, the plurality of heat sinks corresponding to said primary compartment 2 could each be located within the same isolated access compartment 3, or else each heatsink or heat exchanger 7 can face into its own isolated access compartment 3—that is to say that the number of primary compartments 2 might match the number of isolated access compartments 3, or there might be more isolated access compartments 3 than there are primary compartments 2 in certain embodiments. In other embodiments where multiple heat exchangers 7 related to components contained within multiple primary compartments 2 were all located within the same isolated access compartment 3, the number of isolated access compartments 3 might be fewer than the number of primary compartments 2 in the overall system 1. All such combinations, in terms of the numbers and correspondence of primary compartments 2 to isolated access compartments 3 will be understood to be contemplated within the overall scope and intention of coverage of the present invention.

FIG. 5 and FIG. 6 are top views of FIG. 1 and FIG. 2 respectively, showing the system 1 with the isolated compartment access door 4 in closed and open positions. From the top view the positioning of the primary compartment 2 can also be better understood, and in dotted relief the heat producing industrial component 8 is also shown.

As outlined elsewhere in detail, each isolated access compartment 3 containing at least one heat exchanger 7 is physically separate from the corresponding primary compartment 2 or compartments 2 in which the related heat producing industrial components 8 are located, while the industrial components 8 and their related heat exchangers 7 are configured to be in thermal contact with each other through the shared wall 5 shared between the primary compartment or compartments 2 and the isolated access compartment or compartments 3, such that effective heat transfer from the heat producing industrial components 8 to their related heat exchangers 7 is achieved.

The isolated access compartments 3 which are shown in the Figures and exemplary embodiments hereof, as well as the primary compartments 2, would each include door or access panel so as to limit exposure of the components located therein to the external environment while still providing for operator or maintenance access at the appropriate time. For example, in an environment where there may be flying debris, high dust accumulation or the like, it may be useful to shield the heat exchanger 7 from possible damage due to clogging. This would be particularly advantageous in applications such as in mining or other underground operations where there might be significant amounts of particulate debris present in the environment.

The plurality of heat exchangers 7 might be any of a number of configurations including commonly known designs that included vane structures designed to increase the surface area of the heat exchanger or heatsink 7 and thus the rate at which it is able to effect heat transfer and cool the attached component 8 to which it is in thermal contact. Heat exchangers or heat sinks can be comprised of a number of materials including without limitation various metals, graphite or the like. Preferably the heatsink material will have a relatively high thermal conductivity coefficient relative to the cooling media.

The system of the present invention is potentially compatible with a variety of types of cooling media, although it is specifically contemplated that the primary effect and utility of the present invention would be with heat exchangers using air as the cooling media. As outlined in the Figures, in order to increase the rate of heat transfer from the heat producing industrial components 82, the heat exchanger 7, and from the heat exchanger 7 to the surrounding environment, it may be desirable to provide a means by which to circulate the cooling media or the air over the surface area of the heatsink 7. A blower 6 is shown in the Figures herein, configured to move the volume of air over the surface of the heat exchanger 7 within its corresponding isolated access compartment 3—see FIG. 1—thereby improving the amount of heat that can be removed from the heat producing industrial component 8 over time. A blower fan 6 or other apparatus used for maximizing or optimizing the flow of air over the heat exchangers 7 will be understood to those skilled in the art and any type of an add-on apparatus which will maximize airflow over the heat exchanger 7 is contemplated within the present invention.

In some instances, it may be desirable to provide a variable speed blower 6 so the volume of air moved over the heatsink 7 can be varied in response to the amount of heat which is generated from the heat producing industrial component 8. In this type of a configuration the system 1 could further comprise a control unit which sensed the temperature of the heat, producing an electronic component or components 8, and then through a feedback system such as a digital processor would issue instructions to a regulator operative to increase or decrease the blower speed as necessary. In this way, the heat producing industrial components 8 could be kept within a certain design temperature operating range for maximum efficiency, and only as much energy as was required to operate the blower 6 or which could be designed to turn off automatically after the components 8 had been shut down or temperature reduced below a certain desired said temperature to ensure that the components 8 were properly cooled after being taken off-line. Depending on the specific component that comprise the heat producing industrial component, it may be desirable to maintain component temperature within a range of about −55° C. to about 125° C., or from about −40° C. to about 85° C., or from about 0° C. to 70° C.

Referring briefly to FIG. 7, there is shown a side view of the system of FIG. 1 from the opposite side of the sled 1 from the isolated access compartment. Specifically, the primary compartment 2 containing the heat producing industrial component or components 8 is shown, with a door 9 which is open for the purpose of demonstration but in other embodiments and in operation would in all likelihood be closed. This Figure is simply intended to demonstrate with an alternate view the mounting of the components 8 on the wall 5 such that the heat exchanger or exchangers 7 associated there with would pass through an appropriate seal or aperture in the wall 5 into the isolated access compartment 3 on the other side thereof.

The primary advantage of the present invention is that by locating at least one heat exchanger or heatsink 7 corresponding to a heat producing industrial component 8 in a separate isolated access compartment 3 apart from a primary compartment 2 containing the industrial component or components 8, in such a fashion that the heat exchanger 7 in the industrial component 8 to be cool remain in thermal contact, access to the heat exchanger 7 and the isolated access compartment 3 without risking exposure of the industrial components 8 within the primary compartment 2 during operation is achieved. As will be appreciated by those skilled in the art, this permits access to the heat exchanger 7 for cleaning or other servicing without unduly risking damage to the industrial components 8 attached thereto. It also provides the ability to access for cleaning or other purposes the heat exchanger or heatsink 7 without the need for safety purposes or otherwise to shut down the system 1 or to take the components 8 off-line during cleaning or access to the heat exchangers 7. For example, from time to time, heat exchangers can become contaminated by material from the surrounding environment such as dust, dirt or other particulates, which would cling to the surface of the heat exchanger or heatsink. These contaminants, if present, can result in increasing reduction in the efficiency of heat transfer from the heat exchanger to the surrounding cooling medium or air. Eventually contamination can become so significant that the heatsink fails to provide adequate cooling to the component 8 and that can in turn lead to component damage, malfunction or complete failure.

Depending upon the type of cleaning required, it may often be necessary to use various types of electronically conductive cleaners in order to effectively remove contaminants from the heat exchangers. The problem with prior art heatsink and component arrangements lies in the fact the heatsink and the operating components lie in the same physical compartment and that whatever cleaning methods and materials are used to clean the heat exchanger are likely come into contact with the component to which it is attached. Where electronic components are involved, this would require that the component be taken out of service in order to avoid inadvertent short-circuiting of the electronics or electrical systems on the system 1. This would also potentially require drying or other attention in advance of recommissioning the system. By physically separating the heatsink and its attached component into separate adjacent compartments, the present invention allows for the heatsink to be cleaned or otherwise serviced without having to take the component it is thermally connected to out of service. The present invention is in essence modular in nature so that as depicted in FIG. 8 is possible to have more than one heat exchanger 7 servicing array of components 8, each of which could be housed in a plurality of separate compartments.

In some embodiments, the material forming the heat exchanger or heatsink 7, as well as the compartment wall 5 itself, could be fashioned from a thermally conductive material so that heat can transfer from the component 8 through the wall 5 into the heat exchanger 7 and then be dissipated into the air. In this way, the heatsink 7 of the component 8 could be in thermal contact with each other without having to be a direct physical contact. In still other embodiments it may be possible for the heat exchanger or heatsink 7 and the component 8 related thereto to be in direct contact with each other and to be secured with the sealing material that prevents the escape of material from the isolated access compartment 3 and the primary compartment 2, and vice versa.

The heat exchanger 7 itself can also be made of material that reduces the rate at which contaminants accumulate on the heatsink. For example, in some embodiments, the heat exchanger or heatsink is specifically contemplated to be coated with Teflon®, silicone or other similar materials that are resistant to contaminant accumulation or sticking, and/or which might increase the ease with which the heat exchanger could be cleaned. In still other embodiments, the apparatus might include a device that applies electric current to the heat vanes on the heat exchanger 7 in order to provide an electrostatic force that repels contaminants of foreign material and minimizes their adherence to the heat exchanger or heatsink in operation. For example, it is known in the art that electrostatic charges can be applied to a suitable surface in order to attract and remove particles from the air. This is the principle upon which some air purifying systems operate. Thus, by applying these principles in reverse it would be possible to repel contaminants which are suspended in the cooling medium and reduce the need to maintain the heatsink in order to preserve thermal transfer efficiency.

In operation of the overall system of the present invention, the at least one heat producing industrial component 8 within the system 1 can be activated, and heat will be exchanged from that component 8 to the at least one heat exchanger 7 connected thereto. Heat will be exhausted from the industrial component 8 via the heat exchanger 7 through the isolated access compartment 3 corresponding thereto. At such point in time as it is necessary to clean or access the heat exchanger 7 for other purposes, the isolated access compartment 3 can be used without the need to shut down the industrial component 8, at least for short-term maintenance activities. Following the cleaning of the heat exchanger 7 or other maintenance attendants, the isolated access compartment 3 can be closed and regular operations can continue. By limiting the number of times that the primary compartments 2 of the system 1 might need to be opened to access the industrial components 8 contained therein, overall safety of operators as well as the equipment, and the operating efficiency of those industrial components 8 will be maximized, as they will be least exposed to environmental contaminants.

The present invention represents enhancement over prior art methods which have typically included heat exchangers 7 mounted to industrial components 8 all of which are contained in a unitary fashion within a single primary compartment 2, with air then being circulated therethrough for the sake of the error across the heat exchangers 7. Heating of the industrial components 8 themselves will be minimized by the movement of the heat exchangers 7 into an adjacent compartment. As well, there is a significant safety and economic operating package to moving heat exchangers 7 into an adjacent isolated access compartment 3.

As outlined also in passing about the other aspect of the present invention which it is explicitly designed to encompass within this disclosure is the coding of an air heat exchanger or heatsink for use in such a system or environment with a coating resistant to contaminant accumulation such as silicone, Teflon or the like which will allow for increased ease of cleaning, as well as for minimizing the amount of interior which might be attracted to the heat exchanger 7 in either passive or blowing air environments during operation.

The above description is intended to enable a person of skill in the art to practice the invention. It is not intended to detail all possible variations and modifications that might become apparent to one of skill in the art upon reading the description of the invention as presented herein. It will be apparent to those skilled in the art that many more modifications besides those already described are possible without departing from the inventive concepts herein. The inventive subject matter, therefore, is not to be restricted except in the scope of any claims based on the description as provided herein. Moreover, in interpreting both the description and any claims issuing therefrom, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

1. A cooled component system, the system comprising:
a. at least one heat generating component;
b. at least one heat exchanger thermally connected to the at least one heat generating component, said heat exchanger having a heat exchanging surface;
c. a housing comprising at least one accessible primary compartment and at least one separately accessible isolated access compartment, said compartments sharing a wall with an aperture extending there through corresponding to each heat exchanger;
wherein the at least one heat generating component is mounted substantially within the at least one primary compartment with the heat exchanging surface of its corresponding heat exchanger extending through the corresponding aperture such that when in use, heat exchanged from the at least one heat generating component within the primary compartment is exhausted through the isolated access compartment; and
wherein the heat exchanging surface of the at least one heat exchanger is accessible through the isolated access compartment without the need to access the primary compartment.

2. The cooled component system of claim 1, further comprising a cooling means, wherein the cooling means comprises a cooling media and means for moving said media through the interior of the at least one isolated access compartment, such that heat generated by the at least one heat generating component passes from the at least one heat generating component, through the at least one heat exchanger via its heat exchanging surface, and into the cooling media.

3. The cooled component system of claim 2, wherein the cooling means comprises at least one of a gas and a fluid.

4. The cooled component system of claim 3, further comprising a supply of cooling media, means for introducing said cooling media into the interior of the at least one isolated access compartment, moving the cooling media through the interior of the at least one isolated access compartment, and removing said cooling media from the interior of the isolated access compartment.

5. The cooled component system of claim 1, wherein the at least one heat exchanger further comprises vanes on its heat exchanging surface, said vanes configured to increase the effective surface area of the at least one heat exchanger.

6. The cooled component system of claim 4, wherein the means for introducing cooling media into the isolated access compartment comprises at least one of an inlet vent and an inlet conduit. The cooled component system of claim 4, wherein the means for moving cooling media through the interior of the isolated access compartment comprises at least one of a fan, a blower and a pump.

8. The cooled component system of claim 4, wherein the means for removing cooling media from the isolated access compartment comprises at least one of an outlet vent and an outlet conduit.

9. The cooled component system of claim 4, wherein the means for moving cooling media through the interior of the isolated access compartment comprises at least one of a blower and a pump.

10. The cooled component system of claim 1, wherein the at least one primary compartment, and the at least one isolated access compartment each comprise at least one access door, said doors configured to admit access to the interior of said compartments.

11. The cooled component system of claim 2, further comprising a control unit configured to regulate the flow of the cooling media through the interior of the at least one isolated access compartment such that the temperature of the at least one heat generating component is maintained within a desired range.

12. The cooled component system of claim 11, wherein the desired range is from about −55° C. to about 125° C., or from about −40° C. to about 85° C., or from about 0° C. to 70° C.

13. The cooled component system of claim 1, wherein the at least one primary compartment and the at least one isolated access compartment are physically separated, such that materials are substantially prevented from passing from one compartment to the other.

14. The cooled component system of claim 1, wherein the at least one heat exchanger further comprises a coating effective to resist the accumulation of particulate debris on the surface of the at least one heat exchanger.

15. The cooled component system of claim 14, wherein the coating comprises at least one of Teflon® and silicone.

16. The cooled component system of claim 1, further comprising an electrostatic module configured to apply an electrostatic charge to the heat exchanging surface of the at least one heat exchanger, said charge effective to reduce the accumulation of particulate debris on said heat exchanging surface.

17. The cooled component system of claim 1, wherein the system is mounted on a portable sled.

18. The cooled component system of claim 1 wherein the number of heat generating components is one.

19. The cooled component system of claim 1 wherein the number of heat generating components is more than one.

20. The cooled component system of claim 19 wherein the number of primary compartments is one.

21. The cooled component system of claim 19 wherein the number of primary compartments is more than one.

22. The cooled component system of claim 19 wherein the number of isolated access compartments is one.

23. The cooled component system of claim 19 wherein the number of isolated access compartments is more than one.
